(19) United States
(12) Patent Application Publication
(10) Pub. No.: US 2026/0066881 A1
(43) Pub. Date: Mar. 5, 2026

(54) Method for determining a digital finite impulse response filter and associated computer program and determining system

(71) Applicant: THALES, Meudon (FR)

(72) Inventor: Marie AUFFRET, MERIGNAC (FR)

(21) Appl. No.: 19/311,584

(22) Filed: Aug. 27, 2025

(30) Foreign Application Priority Data
Aug. 27, 2024 (FR) 2409146

(51) Int. Cl. H03H 17/02; H03H 17/00

(52) U.S. Cl. CPC H03H 17/0202; H03H 17/0219; H03H 2017/0081

(57) ABSTRACT

A method for determining a finite impulse response filter, including generation of a plurality of individuals presenting configuration parameters, and cyclic implementation of the following operations in relation to each current population of configuration parameters: evaluation by an objective function of each individual, evaluation by at least one constraint function of each individual, selection of a group of individuals among all the individuals based on their evaluations by the objective function and the constraint function and formation of parent individuals, crossover of parent individuals to form a new population, mutation of individuals in the new population, and verification of a stopping criterion.

### CROSS-REFERENCE TO RELATED APPLICATIONS

This application is a U.S. non-provisional application claiming the benefit of French Patent Application No. 24 09146 filed on Aug. 27, 2024, the contents of which are incorporated herein by reference in their entirety.

### FIELD OF THE INVENTION

The present invention relates to a method for determining a finite impulse response filter.

The present invention also relates to a computer program and a determining system associated with this determination method.

The technical field of the invention is that of analog signal processing, for example from different sensors, notably avionic sensors, such as position sensors.

### BACKGROUND OF THE INVENTION

In a known manner, from a reference sinusoidal signal sent to these sensors (often called excitation), the sensors return one or more sinusoidal signals whose amplitude is a known function of the position of the sensor.

To deduce the position of the sensor, it is necessary to measure the amplitude of sinusoidal signals.

The measurement of the amplitude of a sinusoid generally involves a first processing stage that transforms this sinusoidal signal into another signal that comprises an oscillating part superimposed on a continuous part. The oscillating part is an unwanted but inevitable artifact, and the continuous part is proportional to the amplitude and contains the sought information.

A second processing stage is responsible for eliminating the oscillating part while preserving the continuous part. The measurement of the isolated continuous part is then very simple and allows access to the amplitude value.

To perform such processing, a finite impulse response filter (called “FIR” from “Finite Impulse Response”) is generally used. This type of filter is most often used for several reasons, comprising its deterministic and robust nature, in addition to its recovery capability following a disturbance while maintaining low latency.

An FIR-type filter is generally implemented by an embedded computer or at least connected to an interface of such a computer. The embedded computer is, for example, the flight control computer. Thus, this filter is designed for optimal operation with this computer and a particular type of signals.

The computers used to date are designed with interfaces defined at the time of their design. When a new need arises during development or a modification is necessary, the entire design generally needs to be reviewed.

To reduce the size of computers while offering more flexibility, versatile solutions must be developed to parameterize the interfaces through software configuration. This versatility allows the number of interfaces to be reduced by grouping them by nature and configuring their characteristics in a software manner.

Thus, the FIR-type filter implemented by or connected to a classic or versatile computer must also be modified to meet the new need.

However, often, such a modification of the filter cannot be done automatically, and human intervention is generally necessary in the case of classic computers.

Regarding versatile computers, to be accepted on board an aircraft, such a computer must prove that it has been validated on a large number of configurations. This necessity implies that the FIR-type filter is precisely adjusted for each supported configuration, whether it is the computer configurations or the signals. With such important versatility needs (several hundred supported configurations), manual adjustment of the filter to meet the new configurations is no longer feasible.

Thus, there is a need for greater flexibility of FIR-type filters for any new configuration without any human intervention.

### SUMMARY OF THE DESCRIPTION

The invention therefore aims to propose means to ensure great flexibility of FIR-type filters for any new configuration automatically.

To this end, the invention aims at a method for determining a finite impulse response filter comprising a sequence of sinusoidal band-stop filters, each sinusoidal band-stop filter being determined by a set of configuration parameters, the method comprising the following steps:
generation of a plurality of individuals presenting configuration parameters, the individuals forming an initial population of configuration parameters;
cyclic implementation of the following sub-steps in relation to each current population of configuration parameters:
   evaluation by an objective function of each individual of the current population;
   evaluation by at least one constraint function of each individual of the current population;
   selection of a group of individuals among all the individuals of the current population based on their evaluations by the objective function and the constraint function, and formation of parent individuals from individuals from this group;
   crossover of parent individuals to form a new population of configuration parameters;
   mutation of individuals in the new population of configuration parameters;
   verification of a stopping criterion.

According to other advantageous aspects of the invention, the method comprises one or more of the following features, taken individually or according to all technically possible combinations:
the individuals of the initial population are generated randomly within predetermined value ranges;
the set of configuration parameters of each sinusoidal band-stop filter comprises a cutoff frequency and a spacing of this filter;
the objective function is determined by operational parameters comprising at least one element chosen from the group comprising:
   parameters of the signals to be processed by the finite impulse response filter;
   parameters of hardware equipment processing signals to be processed by the finite impulse response filter;
   model of the finite impulse response filter;
   specifications of the finite impulse response filter;
   business constraints;
the objective function corresponds to the difference between the gain of the finite impulse response filter and a predetermined optimal gain limit value;
the gain of the finite impulse response filter is determined by the gain of each sinusoidal band-stop filter and by a moving average gain;
the selection sub-step comprises selecting individuals with smaller evaluations by the objective function than other individuals;
the or each constraint function is determined by operational parameters comprising at least one element chosen from the group comprising:
   parameters of the signals to be processed by the finite impulse response filter;
   parameters of hardware equipment processing signals to be processed by the finite impulse response filter;
   model of the finite impulse response filter;
   specifications of the finite impulse response filter;
   business constraints;
the or each constraint function verifies at least one of the constraints chosen from the group comprising:
   latency constraint;
   template constraint in the frequency domain;
   regular attenuation constraint in a useful band;
   static gain constraint;
   impulse response constraint;
the formation of parent individuals comprises a random selection of individuals in said group of individuals;
the finite impulse response filter further comprises a moving average determined by at least one configuration parameter, said configuration parameter being included in each current population of configuration parameters.

The invention also relates to a computer program including software instructions which, when executed by a computer, implement the method as defined above.

The invention finally relates to a system for determining a finite impulse response filter comprising a sequence of sinusoidal band-stop filters, comprising technical means configured to implement the method as defined above.

### BRIEF DESCRIPTION OF THE DRAWINGS

The invention will appear more clearly upon reading the following description, given solely by way of non-limiting example, and made with reference to the drawings wherein:

FIG. 1 is a view of an analog signal acquisition architecture comprising a filtering device;

FIG. 2 is a detailed view of the filtering device shown in FIG. 1, the filtering device comprising a filtering unit configured to implement a finite impulse response filter;

FIG. 3 is a schematic view of the finite impulse response filter implemented by the filtering unit shown in FIG. 2;

FIG. 4 is a schematic view of a device for determining the filter shown in FIG. 3;

FIG. 5 is a flowchart of a determination method according to the invention, the method being implemented by the device shown in FIG. 4; and

FIGS. 6 to 9 are different illustrations of the implementation of at least some of the steps of the method shown in FIG. 5.

### DETAILED DESCRIPTION OF EMBODIMENTS

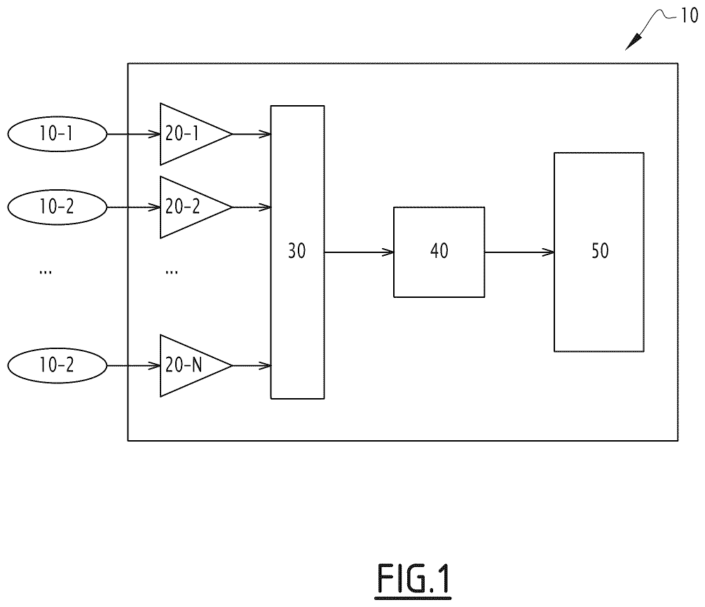

FIG. 1 illustrates an acquisition architecture 10 of analog signals, usable for example in the avionic field. This architecture 10 allows analog signals to be converted into digital signals and transmitted to one or more avionic applications.

According to other embodiments, the acquisition architecture 10 is usable in any other field implementing a conversion of analog signals into digital signals.

Referring to FIG. 1, the acquisition architecture 10 comprises a set of sensors 10-1, . . . ,10-N, a set of signal conditioners 20-1, . . . , 20-N, an analog-to-digital converter 30, a filtering device 40, and one or more software 50.

The sensors 10-1, . . . ,10-N are in number N (N>0) and are, for example, avionic sensors of the same nature or of different natures. Each sensor 10-1, . . . ,10-N is configured more particularly to measure at least one physical quantity or to receive external signals, and to generate, from this measurement or external signals, analog signals. Thus, each sensor 10-1, . . . ,10-N corresponds, for example, to a position, pressure, speed, temperature sensor, or, for example, to a GNSS (“Global Navigation Satellite Systems”) signal sensor or a sensor of any other type of signal related to the position of the aircraft. When it is a position sensor, it may correspond to an electromagnetic sensor, for example, a linear LVDT (“Linear Variable Differential Transformer”) sensor, a rotary RVDT (“Rotary Variable Differential Transformer”) sensor, a rotary resolver sensor, or a rotary SYNCHRO sensor.

The signal conditioners 20-1, . . . , 20-N, whose number depends on the number of sensors 10-1, . . . ,10-N, are connected to them and allow, for example, the analog signals acquired by these sensors 10-1, . . . ,10-N to be amplified and/or shaped. Advantageously, the conditioners 20-1, . . . ,20-N are in number N, just like the sensors 10-1, . . . ,10-N. Thus, each conditioner 20-1, . . . ,20-N is connected to a respective sensor 10-1, . . . ,10-N.

The analog-to-digital converter 30 is connected to all the signal conditioners 20-1, . . . ,20-N and allows the analog signals from the conditioners 20-1, . . . ,20-N to be converted into digital signals. Such a converter 30 is known, for example, under the abbreviation “ADC” (“Analog to Digital Converter”).

The or each software 50 presents for example an avionic application connected to the filtering device 40. Such software 50 is configured to receive digital signals from this filtering device 40 and to process them according to the nature of the sensor 10-1, . . . ,10-N corresponding to these signals. For example, such software 50 is configured to deduce the position of a moving element of the aircraft from the acquired signals from one or more position sensors, to display and/or communicate to any interested system this position and/or the speed of the aircraft. The or each software 50 is implemented by an embedded computer, such as, for example, a flight control computer, known in itself.

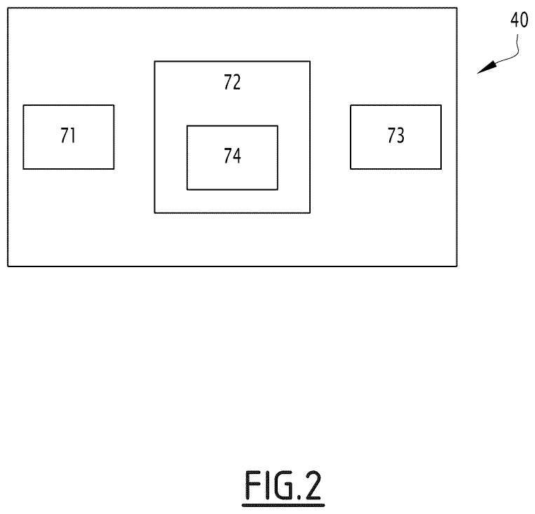

The filtering device 40 is illustrated in more detail in FIG. 2. This filtering device 40 is, for example, implemented at least partially, advantageously entirely, in the form of one or more programmable logic circuits, such as FPGA (“Field Programmable Gate Array”) or a microcontroller. In addition or alternatively, this filtering device 40 is implemented at least partially in the form of one or more software. In this case, these software are stored in an adapted memory and are executable by one or more processors.

Referring to FIG. 2, the filtering device 40 comprises an input module 71, a processing module 72, and an output module 73.

The input module 71 allows the digital signals converted by the analog-to-digital converter 30 to be received.

The processing module 72 allows the converted digital signals to be processed to eliminate their time-varying part. In particular, to do this, the processing module 72 comprises a low-pass filtering unit 74 configured to apply a sinusoidal band-stop filter and, more particularly, a finite impulse response filter, also called FIR (“Finite Impulse Response”) filter.

Finally, the output module 73 allows the signals processed by the processing module 72 to be transmitted to one or more software 50.

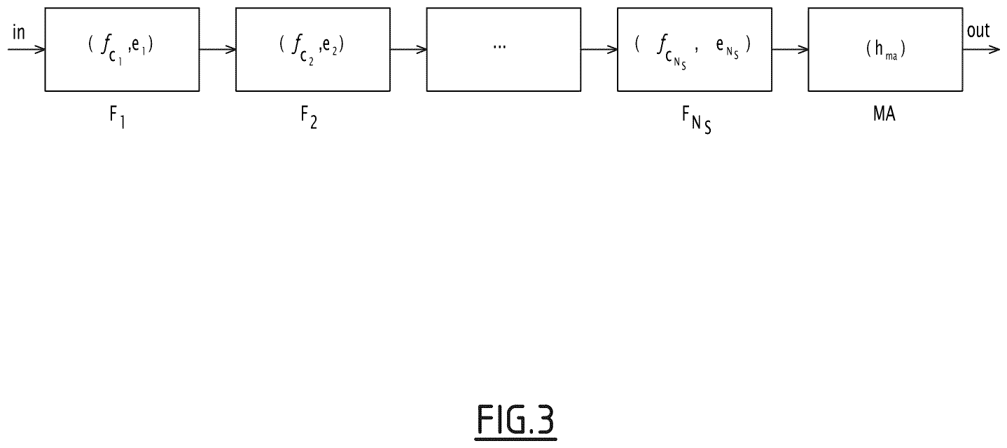

As illustrated in FIG. 3, the FIR-type filter F comprises a sequence of Ns sinusoidal band-stop filters in series and advantageously terminated by a moving average filter MA.

By “sequence of Ns filters,” we mean a chained application of these filters so that each subsequent filter (except the first filter) is applied to the output of the previous filter. The first filter is applied to the initial function. The moving average is applied to the output of the filter F_{Ns}.

By “sinusoidal band-stop filter” also called a CBS filter, we mean a digital FIR-type filter whose gain curve as a function of frequency is a sinusoidal function of frequency.

More particularly, in the case of a sinusoidal band-stop filter, its gain curve Hᵢ(f) is a sinusoidal function of frequency.

Each CBS filter Fᵢ is determined by a set of configuration parameters.

These configuration parameters can take different forms, such as cutoff frequencies, filter coefficients, damping factors, etc.

Advantageously, in the example described below, the configuration parameters of each CBS filter Fᵢ comprise a cutoff frequency f_{c}_{ᵢ} and a spacing eᵢ of this filter.

The moving average MA is also determined by a set of configuration parameters comprising at least one configuration parameter, for example its horizon hₘₐ.

Thus, in the example described below, the total number Nₚof configuration parameters of the filter F is equal to 2Ns+1.

Furthermore, each CBS filter Fᵢ is determined by a filter model determining its gain function Hᵢ(f) and its impulse response hᵢ[n].

These functions Hᵢ(f) and hᵢ[n] are for example chosen as follows:

$${H}_{i} ( f ) = \frac{1}{2 − 2 cos ( 2 π {f}_{{c}_{i}} {e}_{i} {T}_{s} )} \frac{{e}^{j {e}_{i} 2 π {fT}_{s}} − 2 cos ( 2 π {f}_{{c}_{i}} {e}_{i} {T}_{s} ) + {e}^{− j {e}_{i} 2 π {fT}_{s}}}{{e}^{j {e}_{i} 2 π {fT}_{s}}} ,$$

$${h}_{i} [ n ] = \frac{1}{2 − 2 cos ( 2 π {f}_{{c}_{i}} {e}_{i} {T}_{s} )} δ [ n ] − \frac{2 cos ( 2 π {f}_{{c}_{i}} {e}_{i} {T}_{s} )}{2 − 2 cos ( 2 π {f}_{{c}_{i}} {e}_{i} {T}_{s} )} δ [ n − {e}_{i} ] + \frac{1}{2 − 2 cos ( 2 π {f}_{{c}_{i}} {e}_{i} {T}_{s} )} δ [ n − 2 {e}_{i} ]$$

where:
Tₛ is the sampling period.

Furthermore, the gain function Hₘₐ(f) for the moving average MA is chosen as follows:

$${H}_{ma} ( f ) = \frac{1}{{h}_{ma}} \frac{1 - {e}^{- j 2 π f {h}_{ma} {T}_{s}}}{1 - {e}^{- j 2 π {fT}_{s}}} .$$

Thus, the gain |H(f)| of the filter F in the frequency domain is expressed as follows:

$$\vert H ( f ) \vert = \vert {H}_{ma ( f )} \vert ( {\prod }_{i = 1}^{Ns} \vert {H}_{i} ( f ) \vert ) == \vert \frac{1}{{h}_{ma}} \frac{1 - {e}^{- j 2 π f {h}_{ma} {T}_{s}}}{1 - {e}^{- j 2 π {fT}_{s}}} \vert ( {\prod }_{i = 1}^{Ns} \vert \frac{cos ( 2 π {fe}_{i} {T}_{s} ) - cos ( 2 π {f}_{{c}_{i}} {e}_{i} {T}_{s} )}{1 - cos ( 2 π {f}_{{c}_{i}} {e}_{i} {T}_{s} )} \vert ) .$$

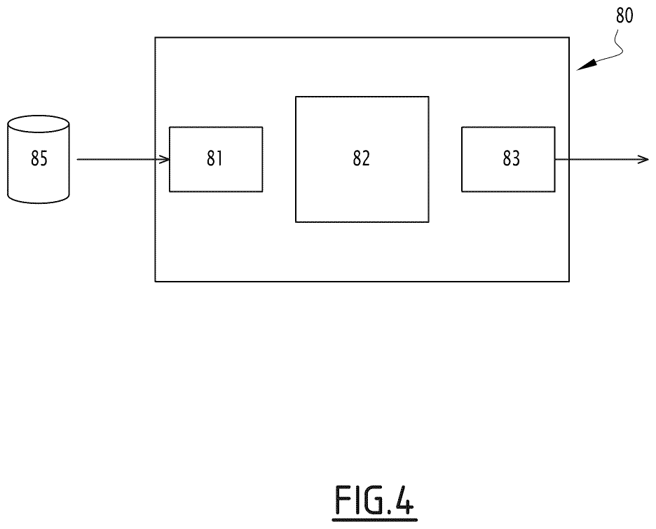

FIG. 4 illustrates a determination device 80 allowing the FIR-type filter F to be determined, as illustrated in FIG. 3. In particular, the determination device 80 allows the configuration parameters of each CBS filter and the moving average MA to be determined, as will be explained in more detail later.

The determination device 80 is, for example, implemented at least partially in the form of one or more programmable logic circuits, such as FPGA (“Field Programmable Gate Array”). In addition or alternatively, this determination device 80 is implemented at least partially in the form of one or more software. In this case, these software are stored in an adapted memory and are executable by one or more processors.

Referring to FIG. 4, the determination device 80 comprises an input module 81, a processing module 82, and an output module 83.

The input module 81 allows operational parameters to be received to adapt the FIR-type filter to its operating environment. These operational parameters are, for example, from a database 85 and comprise at least one element chosen from the group comprising:
parameters of the signals to be processed by the finite impulse response filter;
parameters of hardware equipment processing signals to be processed by the finite impulse response filter;
model of the finite impulse response filter;
specifications of the finite impulse response filter;
business constraints.

The parameters of the signals to be processed comprise for example an excitation frequency fₑₓ, a harmonic frequency fₕ, and a noise level Gₛ(f) of these signals. These parameters are, for example, determined based on the nature of the sensors 10-1, . . . ,10-N and the nature of the signals generated by these sensors.

The parameters of hardware equipment notably comprise parameters of the conditioners 20-1, . . . , 20-N, the analog-to-digital converter 30, and/or the computer implementing the or each software 50. These parameters comprise, for example, the sampling period Tₛ and/or the quantification method Gᵢₙ(f) of the analog-to-digital converter 30.

The filter model comprises a definition of the gain functions Hᵢ(f) and impulse response hᵢ[n] as defined previously.

The filter specifications notably comprise a bandwidth Gₘᵢₙ(f), a maximum latency δₘₐₓ, a minimum required filtering quality in high-frequency Gₘₐₓ(f), etc.

The business constraints are, for example, related to the field of use of the filter F and notably the sensors 10-1, . . . ,10-N. For the aeronautical field, it may, for example, be a quasi-Gaussian impulse response, a regular impulse response, a regular frequency response in the bandwidth of the signal, etc.

The processing module 82 allows all the operational parameters to be processed to determine the configuration parameters, by implementing at least some of the steps of a determination method that will be explained in detail later.

Finally, the output module 83 allows the FIR-type filter and notably the configuration parameters of this filter to be transmitted to any interested system and notably to the processing module 72 of the filtering device 40 implementing the filtering of the digital signals converted by the analog-to-digital converter 30.

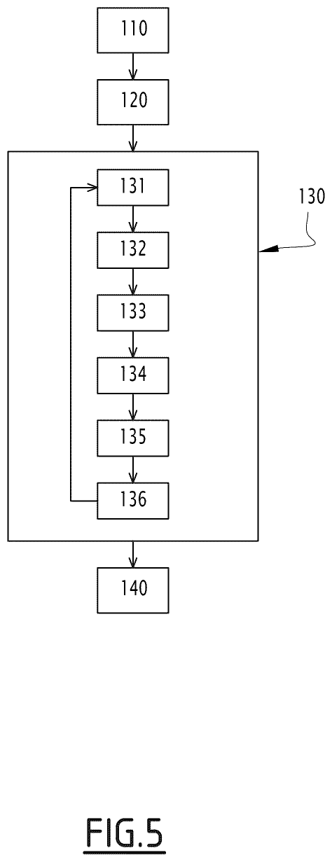

The determination method implemented by the determination device 80 will now be explained with reference to FIG. 5 illustrating a flowchart of its steps.

During an initial step 110, the input module 81 receives the operational parameters as defined above or an update of these parameters. This can, for example, be done at the request of the filtering device 40 following a configuration change in its environment.

Then, the input module 81 transmits the received operational parameters to the processing module 82.

Then, the processing module 82 implements a genetic algorithm during the following steps to determine the configuration parameters of the filter F.

In particular, during step 120, the processing module 82 generates a plurality of individuals presenting configuration parameters. These individuals then form an initial population.

For example, each individual presents the sets of configuration parameters of all the CBS filters F and the moving average MA.

Advantageously, each individual is chosen randomly within a predetermined value range. This value range can, for example, be predetermined based on at least some operational parameters.

Alternatively, in the case of an update of the filter F, each individual corresponds to the sets of configuration parameters of all the CBS filters Fᵢ and the moving average MA, determined previously.

During the next step 130, the processing module 82 cyclically implements sub-steps 131 to 136 in relation to each current population of configuration parameters. Initially, the current population corresponds to the initial population determined during step 120.

During sub-step 131, the processing module evaluates an objective function of each individual of the current population.

In particular, the objective function allows a value, also called score, to be associated with each individual, characterizing the survival capacity of the individual.

Advantageously, in relation to the same individual, the objective function is calculated only once when this individual moves to the next generation.

According to the invention, the optimization problem determining the choice of the objective function is reduced to an area problem between the gain curve of the filter F in the frequency domain and an optimal gain limit value corresponding to the noise level Gₛ(f) of the signals to be processed, for a frequency band [a₁, b₁]. The objective of the optimization problem is then to minimize this area.

This choice was made following the desire to favor a filter that is globally close to the optimal gain limit curve to have a good performance against noise. The area is a good way to weight this global optimization to reject noise present across the spectrum.

Seeking to attenuate high frequencies beyond the optimal gain limit value does not bring additional interest because the disturbances to be eliminated are not of that order. Thus, the optimal gain limit value is defined as the one that eliminates all plausible disturbances.

Accordingly, the objective function used is f₁(x):

$${f}_{1} ( x ) = {\int }_{{a}_{1}}^{{b}_{1}} ( \vert {H}^{*} ( f ) \vert - {G}_{s} ( f ) ) df \\ where : \\ \vert {H}^{*} ( f ) \vert = \{ \begin{matrix}\vert H ( f ) \vert , & \vert H ( f ) \vert \geq {G}_{s} ( f ) \\ {G}_{s} ( f ) , & \vert H ( f ) \vert < {G}_{s} ( f )\end{matrix}$$

The function |H(f)| corresponds to the gain of the filter F as defined previously.

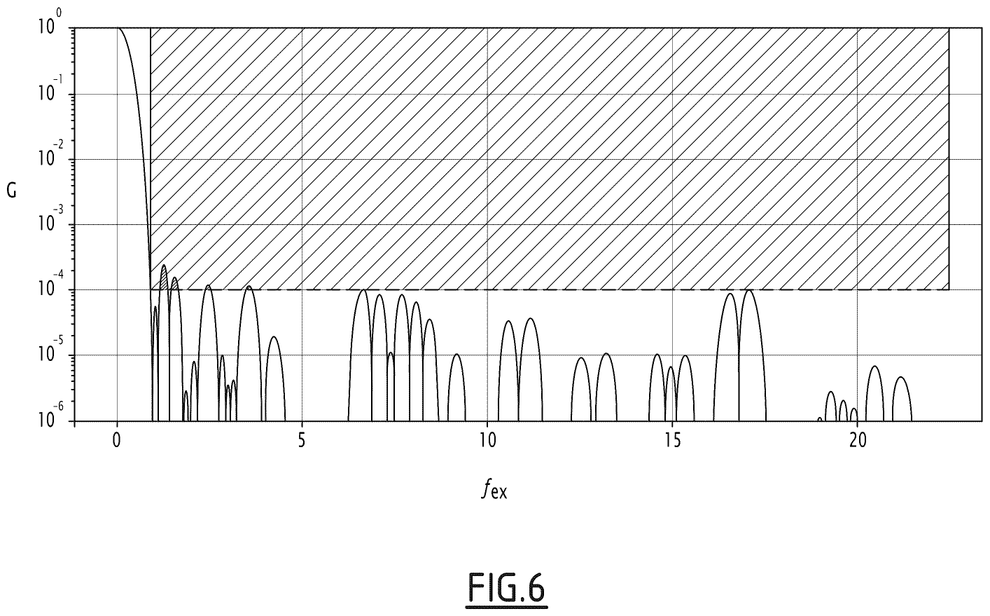

FIG. 6 illustrates the frequency response G at different excitation frequencies fₑₓ of the FIR-type filter, represented by a solid black line. Here, the optimal gain limit target, represented by a dotted black line, is a constant Gₛ(f)=10⁻⁴ over the frequency band [fₑₓ,fₘₐₓ]. The hatched region delineates the space where the optimization algorithm strives to keep the gain curve below. The objective function represents the evaluation of the densely hatched area.

During sub-step 132, the processing module 82 evaluates each individual of the current population by at least one constraint function, advantageously by several constraint functions.

In particular, during this step, several constraint functions are applied to label the individuals (i.e., sets of configuration parameters) to distinguish individuals that meet the filter specification from those that do not.

For example, an individual that meets all the constraint functions is labeled as a “feasible solution.” An individual that does not meet at least one constraint function is labeled as an “infeasible solution.”

The constraint functions are, for example, written in the form of inequality. A constraint function is not met if its evaluation on the corresponding individual gives a strictly positive result. Otherwise, this constraint function is met.

Advantageously, according to the invention, a constraint function can be added or eliminated based on the filter F specification to be obtained.

Furthermore, advantageously, each constraint function is determined at least partially based on operational parameters.

Below are some examples of constraint functions.

In particular, according to this example, the or each constraint function verifies one of the constraints chosen from the group comprising:
latency constraint;
template constraint in the frequency domain;
regular attenuation constraint in a useful band;
static gain constraint;
impulse response constraint.

The latency constraint can be expressed in different forms depending on the filter F specification. For example, in the form of an intrinsic delay of the filter (i.e., the abscissa of the center of gravity of the weight function) or in the form of a delay of the time response of the filter to a ramp. Other expressions of latency can be easily incorporated as constraints in the algorithm. Two examples are detailed below for illustrative purposes.

A first example relates to a constraint on the intrinsic delay of the filter.

According to this example, the intrinsic delay of the filter must not exceed the maximum allowed latency of the filter δₘₐₓ. Therefore, all filters with a delay strictly greater than δₘₐₓ are rejected. The constraint can be defined as follows:

$${g}_{1} ( x ) = {T}_{s} ( \frac{{h}_{ma}}{2} + {\sum }_{i = 1}^{N} {e}_{i} - 0.5 ) - {δ}_{max} \leq 0.$$

A second example relates to a constraint on the delay of the time response to the filter to a ramp.

According to this example, the delay of the time response of the filter to a ramp must not exceed the maximum allowed latency of the filter δₘₐₓ. The filter being sampled at a period Tₛ, the delay is measured as the difference between the sample of the midpoint of the excitation n_{exc} and the sample of the midpoint of the time response nᵣₑₚ.

The ramp excursion is taken between 0V and 10V (these values can be configured according to the filter specification). Since the filter has a unit gain, the ramp of the time response has the same excursion range as the excitation. Thus, the voltage value at mid-excursion is 5V, and the sample closest to this value is noted nᵣₑₚ.

Therefore, all filters with a delay strictly greater than δₘₐₓ are rejected. The constraint can be defined as follows:

$${g}_{2} ( x ) = {T}_{s} ( {n}_{rep} - {n}_{exc} ) - {δ}_{max} \leq 0.$$

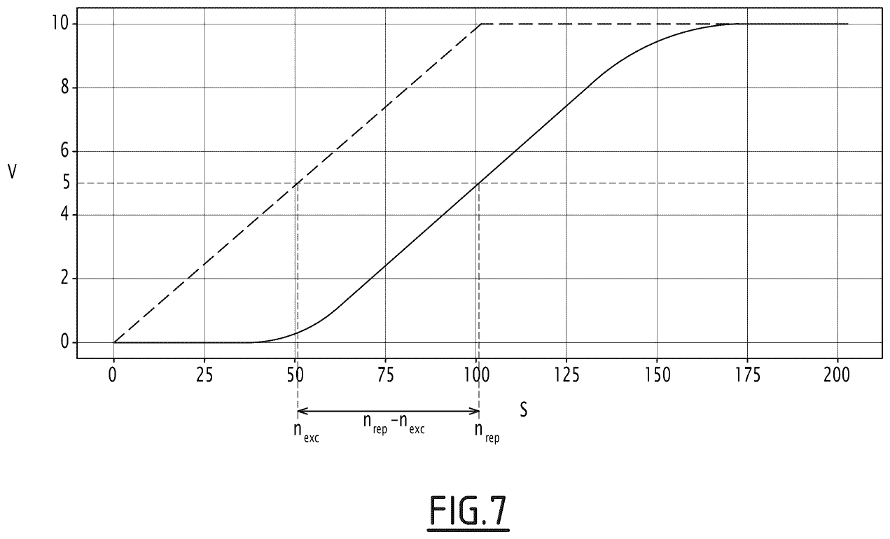

The application of this constraint is illustrated in the graph shown in FIG. 7, wherein the S-axis represents the number of samples, and the V-axis represents the amplitude (in volts) of the signals. In this graph, the dashed line corresponds to the amplitude of the excitation ramp, and the solid line corresponds to the amplitude of the response of the filter to the excitation ramp. Furthermore, the points on the graph correspond to the samples of the midpoint of the excitation n_{exc} and the samples of the midpoint of the time response nᵣₑₚ.

The template constraint in the frequency domain allows one or more constraints to be included so that the gain curve of the filter is entirely below a curve (noted G₁(f), for example) in the frequency domain. This constraint is written as follows over the frequency band [f₁,f₂]:

$${g}_{3} ( x ) = \vert {H}_{i} ( f ) \vert - {G}_{1} ( f ) \leq 0 , ∀ f ∈ [ {f}_{1} , {f}_{2} ]$$

This allows definition of a frequency band to be eliminated.

It is also possible to include one or more constraints so that the gain curve of the filter is entirely above a curve (noted G₂ (f), for example) in the frequency domain. This constraint is written as follows over the frequency band [f₃, f₄]:

$${g}_{4} ( x ) = {G}_{2} ( f ) - \vert {H}_{i} ( f ) \vert \leq 0 , ∀ f ∈ [ {f}_{3} , {f}_{4} ]$$

This allows definition of a frequency band to be preserved.

Thus, by combining constraints of type g₃ and/or g₄ type, all templates can be represented in the solution exploration algorithm. It is thus easy to constrain the exploration of solution filters based on the specified need (e.g., bandwidth width, sharp cuts on certain parts of the spectrum based on disturbances to be rejected, elimination of harmonics, etc.).

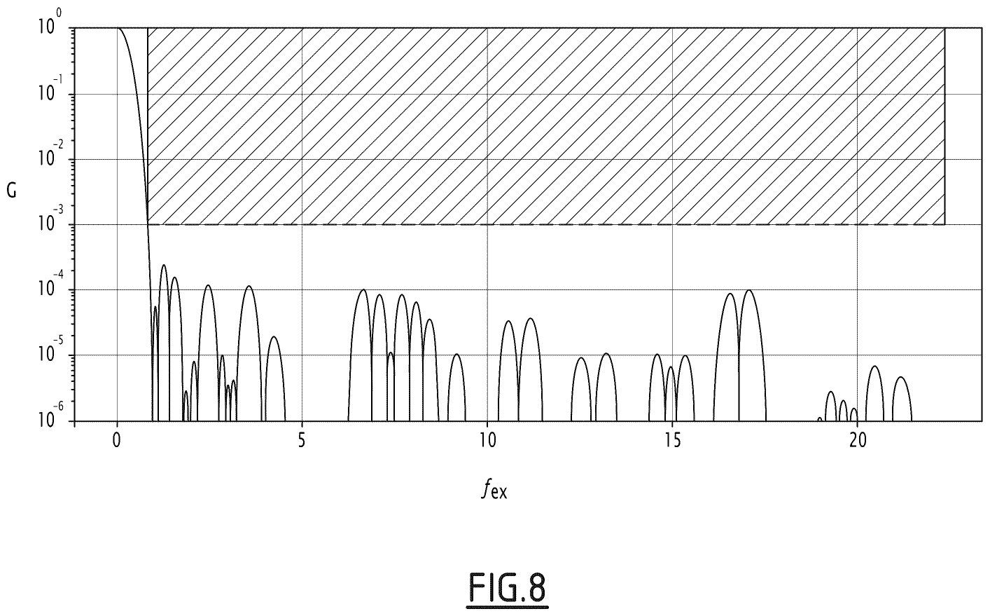

FIG. 8 illustrates a graphical representation of the constraint function of type g₃. In this figure, the frequency response G of the filter F is represented by a solid black line. The gain limit curve not to be exceeded is represented by a dotted black line. Here, in this simplified version for illustrative purposes, G₁ is a constant, i.e. G₁(f)=10⁻³, over the frequency band [fₑₓ,fₘₐₓ]. The hatched region delineates the space where the optimization algorithm imposes keeping the gain curve below.

The regular attenuation constraint in a useful band prevents singularities in the low-frequency part of the spectrum. In particular, a filter singularity means that certain input stimuli (i.e., sensor movements or signal disturbances) will give very different results from neighboring stimuli. However, it is generally desirable to avoid such singularities, especially in the aeronautical field.

The filter also needs to be constrained in the useful band so that it has regular attenuation. In the case of using the filter F, the low frequencies correspond to the frequency band of the movements of the sensor. In this area, the gain curve must be perfectly controlled and regular. Knowing that it must be decreasing, a monotonicity constraint is expressed as follows:

$${g}_{5} ( x ) = ⌈ \vert H ( f + df ) \vert - \vert H ( f ) \vert ⌉ \leq 0 , ∀ f ∈ [ 0 , {f}_{max} ]$$

where df denotes a step to be adjusted based on the required precision.

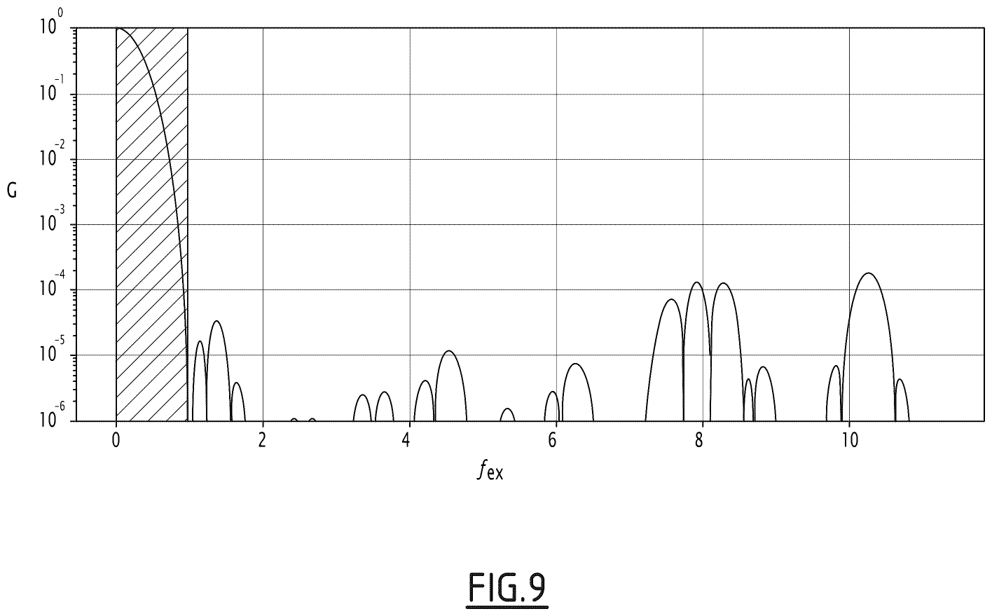

FIG. 9 illustrates a graphical representation of the constraint function of type g₅. In this representation, the hatched area represents the zone where the frequency response must be strictly decreasing.

The static gain constraint of a CBS filter Fᵢ is expressed as follows:

$$\vert {H}_{{0}_{i}} ( f ) \vert = \frac{1}{2 - 2 cos ( 2 π {f}_{{c}_{i}} {e}_{i} {T}_{s} )} , ∀ i ∈ [ 1 , … , N ] .$$

To prevent the gain of the filter from exploding if one of the filters Fᵢ has the denominator of its static gain close to 0, it is necessary to restrict the value of the static gains for each stage. Thus, each static gain must be below a certain value G₀_{_{max′}}.

The constraint can be implemented as follows:

$${g}_{6} ( x ) = {\sum }_{i = 1}^{N} {δ}_{i} \leq 0 , où {δ}_{i} = \{ \begin{matrix}1 , & si \vert {H}_{{0}_{i}} ( f ) \vert \geq {G}_{{0}_{max}} \\ 0 , & sinon\end{matrix}$$

The impulse response constraint is explained by the fact that the filter F must have an impulse response of a particular shape, for example, Gaussian, to achieve performance objectives.

However, depending on the setting of the chain, the association of different CBS filters does not automatically lead to a quasi-Gaussian impulse response. Moreover, the association of sinusoidal filters can potentially create these singularities.

Hence the presence in the sub-step of a monotonicity constraint of the impulse response. The combination of this constraint with that of proximity to a normally distributed Gaussian allows all plausible singularities to be avoided.

The monotonicity constraint of the impulse response aims to achieve the objective that the first half of the impulse response is strictly increasing and the second half is strictly decreasing.

This constraint is expressed as follows:

$${g}_{7} ( x ) = \{ \begin{matrix}⌈ h [ n ] - h [ n + 1 ] ⌉ \leq 0 , & ∀ n ∈ [ 0 , ⌊ \frac{{n}_{ir} - 1}{2} ⌋ ] \\ ⌈ h [ n + 1 ] - h [ n ] ⌉ \leq 0 , & ∀ n ∈ [ ⌈ \frac{{n}_{ir} - 1}{2} ⌉ , {n}_{ir} - 1 ]\end{matrix}$$

where nᵢᵣ represents the number of points of the impulse response.

The constraint g₇, as expressed, counts the number of points that do not respect monotonicity. If monotonicity is respected, g₇(x)=0 and the solution filter is accepted (i.e., labeled as feasible). Otherwise, g₇(x)≥1 and the solution filter is labeled as infeasible.

The proximity constraint to a desired curve (e.g., Gaussian) is expressed as follows:

$${g}_{8} ( x ) = {R}_{min}^{2} - {( {r}_{h \hat{h}} )}^{2} \leq 0$$

where

$${R}_{min}^{2}$$

corresponds to the smallest acceptable value of a variation coefficient R², varying between 0 and 1, and corresponding to a statistical measure of the precision with which regression predictions approximate observed values. R²=1 indicates that the prediction perfectly follows reality (in other words, that the observed data corresponds to the measured data).
r_{xy} corresponds to a Pearson correlation coefficient (PCC) squared. The PCC measures the linear correlation between two data sets. It represents the ratio between the covariance of two variables and the product of their standard deviations. In other words, it is a normalized measure of covariance. The PCC can be expressed as follows:

$${r}_{xy} = \frac{{\sum }_{i = 1}^{n} ( {x}_{i} - \overline{x} ) ( {y}_{i} - \overline{y} )}{\sqrt{{\sum }_{i = 1}^{n} {( {x}_{i} - \overline{x} )}^{2}} \sqrt{{\sum }_{i = 1}^{n} {( {y}_{i} - \overline{y} )}^{2}}}$$

where n is the sample size.
   h and ĥ define a Gaussian model adjusted to the impulse response as follows:

$$\hat{h} [ n ] = a exp ( - \frac{{( n - μ )}^{2}}{2 {σ}^{2}} ) \\ where a = max ( h ) , μ = \frac{E ( nh )}{E ( h )} et σ = \frac{1}{a \sqrt{2 π}} .$$

During sub-step 133, the processing module 82 selects a group of individuals among all the individuals of the current population based on their evaluations by the objective function and each constraint function.

In particular, individuals with both types of labels (i.e., “feasible solution” and “infeasible solution”) can be selected. Depending on the current iteration of the sub-step, the proportion of selected individuals labeled as “infeasible solution” can gradually decrease until reaching 0. Thus, during the last iterations, only individuals labeled as “feasible solution” can be selected. This may be necessary because, during the first generations, the proportion of infeasible individuals in the population is still very high.

Then, the individuals are ranked in ascending order of the corresponding objective function values, and the first M individuals are retained. The number M is, for example, a parameter of the method. In other words, during this sub-step, only individuals with the smallest objective function values (i.e., the smallest scores and thus the most adapted individuals) are chosen.

Then, among all the retained individuals, the processing module 82 chooses a subset to form parent individuals. This subset is chosen, for example, randomly.

During sub-step 134, the processing module 82 applies a crossover operator to the parent individuals to generate one or more children.

This crossover operator can take different forms. It is possible, for example, to choose the operator known as “Simulated Binary Crossover” (SBX).

During sub-step 135, the processing module 82 applies a mutation operator to each child created during the previous sub-step.

This mutation operator can also take different forms. It is possible, for example, to choose a polynomial distribution operator (known as “Polynomial Mutation”).

During sub-step 136, the processing module 82 verifies a stopping criterion and when it is met, stops the execution of step 130.

The stopping criterion varies depending on the complexity of the algorithm to converge to ensure quality results.

An example of a stopping condition can be after a certain number of generations or based on the objective function value. For example, when the gain |H(f)| of the filter F is entirely below the threshold Gₛ(f), the stopping criterion is met.

Advantageously, the stopping criterion can only be met on a solution labeled as feasible.

During the next step 140, the output module 83 transmits the determined filter and notably the configuration parameters of this filter to any interested system, such as the processing module 72 of the filtering device 40. The filtering device 40 can thus implement filtering of signals from sensors 10-1, . . . ,10-N.

It is then understood that the present invention presents a number of advantages.

First, the method according to the invention allows an FIR-type filter to be determined automatically and adapted to any change in the environment wherein this filter operates.

Thus, the filter can be used by versatile computers and can be easily adapted to any change that may occur in such a computer.

According to different examples of application of the invention, the filter obtained by the determination method according to the invention meets the following criteria, in accordance with the filter specification for each possible configuration:
excellent filtering performance thanks to quasi-Gaussian filtering ensured by respecting the gain curve templates in the frequency domain and the impulse response of the filter;
low latency concerning the intrinsic delay of the filter and the time response delay to a ramp;
great robustness concerning sensor signal disturbances (noise, harmonics, crosstalk, etc.);
great robustness concerning uncertainty on the main frequency of the sensor;
great robustness concerning the quantification of coefficients on the computer;
stability of the cascade filter guaranteed by limiting the static gain value of each stage.

Of course, many other embodiments of the invention are also possible.

1. A method for determining a finite impulse response filter comprising a sequence of sinusoidal band-stop filters, each sinusoidal band-stop filter being determined by a set of configuration parameters, the method comprising:
generating a plurality of individuals presenting configuration parameters, the individuals forming an initial population of configuration parameters; and
cyclically performing the following operations in relation to each current population of configuration parameters:
evaluating, by means of an objective function, each individual of the current population;
evaluating, by means of at least one constraint function, each individual of the current population;
selecting a group of individuals among all the individuals of the current population based on their evaluations by the objective function and the at least one constraint function;
forming parent individuals from individuals among the selected group;
crossing over parent individuals to form a new population of configuration parameters;
mutating individuals in the new population of configuration parameters; and
verifying a stopping criterion.

2. The method according to claim 1, further comprising randomly generating individuals of the initial population within predetermined value ranges.

3. The method according to claim 1, wherein the set of configuration parameters of each sinusoidal band-stop filter comprises a cutoff frequency and a spacing of this filter.

4. The method according to claim 1, further comprising determining the objective function by operational parameters comprising at least one element chosen from the group consisting of:
parameters of the signals to be processed by the finite impulse response filter;
parameters of hardware equipment processing signals to be processed by the finite impulse response filter;
model of the finite impulse response filter;
specifications of the finite impulse response filter; and
business constraints.

5. The method according to claim 1, wherein the objective function corresponds to the difference between the gain of the finite impulse response filter and a predetermined optimal gain limit value.

6. The method according to claim 5, further comprising determining the gain of the finite impulse response filter by the gain of each sinusoidal band-stop filter and by a moving average gain.

7. The method according to claim 5, wherein said selecting comprises selecting individuals with smaller evaluations by the objective function than other individuals.

8. The method according to claim 1, further comprising determining the constraint function by operational parameters comprising at least one element chosen from the group consisting of:
parameters of the signals to be processed by the finite impulse response filter;
parameters of hardware equipment processing signals to be processed by the finite impulse response filter;
model of the finite impulse response filter;
specifications of the finite impulse response filter; and
business constraints.

9. The method according to claim 1, wherein each of the at least one constraint function verifies at least one of the constraints chosen from the group consisting of:
latency constraint;
template constraint in the frequency domain;
regular attenuation constraint in a useful band;
static gain constraint; and
impulse response constraint.

10. The method according to claim 1, wherein said forming comprises randomly selecting individuals from among the selected group of individuals.

11. The method according to claim 1, wherein the finite impulse response filter further comprises a moving average determined by at least one configuration parameter, the configuration parameter being comprised in each current population of configuration parameters.

12. A non-transitory computer-readable medium storing program instructions which, when executed by a computer, cause the computer to perform the method of claim 1.

13. A determination system of a finite impulse response filter comprising a sequence of sinusoidal band-stop filters, comprising a processor performing the method of claim 1.
